(19) United States
(12) Patent Application Publication
(10) Pub. No.: US 2016/0293820 A1
(43) Pub. Date: Oct. 6, 2016

(54) Thermoelectric Conversion Element, Method of Manufacturing the Same, and Thermoelectric Conversion Module

(71) Applicant: HITACHI CHEMICAL COMPANY, LTD., Chiyoda-ku, Tokyo (JP)

(72) Inventors: Tomotake TOHEI, Tokyo (JP); Shinichi FUJIWARA, Tokyo (JP); Etsuko TAKANE, Tokyo (JP); Zenzou ISHIJIMA, Tokyo (JP); Takahiro JINUSHI, Tokyo (JP); Motohiro NEGISHI, Tokyo (JP)

(73) Assignee: Hitachi Chemical Company, Ltd., Tokyo (JP)

(21) Appl. No.: 15/037,114

(22) PCT Filed: Jul. 2, 2015
(86) PCT No.: PCT/JP2015/069168

§ 371 Date: May 17, 2016

(30) Foreign Application Priority Data
Oct. 7, 2014 (JP) 2014-206290

(51) Int. Cl. H01L 35/14; H01L 27/16; H01L 35/02; H01L 35/32; H01L 35/34

(52) U.S. Cl. CPC H01L 35/14; H01L 35/32; H01L 35/34; H01L 35/02; H01L 27/16

(57) ABSTRACT

There is provided a thermoelectric conversion element and a thermoelectric conversion module capable of ensuring a temperature difference between the front and the rear of the thermoelectric conversion element even in a high-temperature environment and presenting a high power generation performance. The thermoelectric conversion element including a sintered body constitutes a crystal grain laminated in a transverse direction in which a length in a longitudinal direction of the crystal grain is longer than a length in the transverse direction using at least some of crystal grains constituting the sintered body.

### TECHNICAL FIELD

The present invention relates to a thermoelectric conversion element that converts thermal energy into electric energy and a method of manufacturing the same.

### BACKGROUND ART

A thermoelectric conversion module that converts thermal energy into electric energy using Seebeck effect is characterized in that it includes no drive unit, has a simple structure, requires no maintenance, and the like, but it has been used only in limited products such as a space power supply because of its low energy conversion efficiency. In an effort of achieving an environmentally friendly society, however, it now attracts attention as a method of retrieving waste heat as the thermal energy, and it is expected to be deployed into products related to an incinerator, an industrial furnace, an automobile, and the like. Especially, when using waste heat from an industrial furnace or an exhaust pipe of an automobile, it is conceived that the thermoelectric conversion module should be used in a high-temperature environment in which a temperature difference between the front and the rear of the thermoelectric conversion module is in the order of 300 to 600° C. In such a background, a further improvement in power generation performance of the thermoelectric conversion module for high temperature is desired.

The performance of the thermoelectric conversion module is determined by the following performance index Z determined by a Seebeck coefficient α (V/° C.), a thermal conductivity k (W/m·K), and a specific resistance ρ (Ω·m).

$$Z = \frac{{α}^{2}}{k \cdot ρ} \qquad Equation 1$$

That is, in order to improve the thermoelectric performance, it is required to increase the Seebeck coefficient α, and to reduce the thermal conductivity k and the specific resistance ρ. Moreover, the Seebeck coefficient of the thermoelectric conversion element is several tens of μV/° C. to hundreds of μV/° C., and thus the thermoelectromotive force per unit temperature difference in a single thermoelectric conversion element is low. Therefore, in order to obtain a high output voltage, connecting the thermoelectric conversion elements in series and ensuring the temperature difference by increasing the temperature difference between the front and the rear of the thermoelectric conversion element will greatly contribute to the improvement of the power generation performance.

Patent Literature 1 describes a thermoelectric conversion material that is a solidified compact of a nanowire containing at least one element selected from a group of Bi and Sb and at least one element selected from a group of Te and Se, wherein the diameter of the nanowire or the length of a diagonal in a cross section perpendicular to the longitudinal axis is 500 nm or shorter, the length is 1 μm or longer, and the longitudinal axis of the nanowire is oriented in one direction (Claim 1).

### CITATION LIST

### Patent Literature

Patent Literature 1: Japanese Unexamined Patent Application Publication No. 2005-93454

### SUMMARY OF INVENTION

### Technical Problem

In Patent Literature 1, the thermal electrical conductivity is reduced by orienting the nanowire that constitutes the thermoelectric element in a direction horizontal to a heat flow generated in the thermoelectric element. However, in Patent Literature 1, because the orientation of the nanowire is horizontal to the heat flow direction in the element, the effect of reducing the thermal conductivity is not very large. In addition, because the operating environmental temperature of the thermoelectric conversion element composed primarily of Bi, Sb, Te, and/or Se is limited to relatively low temperature of 200° C. or lower, it is difficult to use it in a high temperature range (300 to 600° C.), and the thermoelectric conversion element using Bi, Sb, Te, and/or Se has a problem with environmental adaptability.

To solve the above problem, an object of the present invention is to provide a thermoelectric conversion element and a thermoelectric conversion module which can be used in a high temperature range, and have excellent power generation performance with a low environmental load and low cost.

### Solution to Problem

To achieve the aforementioned object, the present invention employs the configurations described in the appended claims.

The present invention includes a plurality of means for solving the above problems. One example of the thermoelectric conversion element according to the present invention would be a thermoelectric conversion element comprising a sintered body, wherein a crystal grain laminated in a transverse direction in which a length in a longitudinal direction of the crystal grain is longer than a length in the transverse direction is constituted using at least some of crystal grains constituting the sintered body.

On example of a method of manufacturing a thermoelectric conversion element according to the present invention would be a method of manufacturing a thermoelectric conversion element comprising a sintered body, including the step of forming a crystal grain laminated in a transverse direction in which a length in a longitudinal direction is longer than a length in the transverse direction by heat and pressurize the sintered body in a uniaxial direction.

Another example of the method of manufacturing the thermoelectric conversion element according to the present invention would be a method of manufacturing a thermoelectric conversion element including a sintered body, including the step of forming a crystal grain laminated in a transverse direction in which a length in a longitudinal direction is longer than a length in the transverse direction using at least some of crystal grains constituting the sintered body by sintering a compound in a flattened shape or a flake shape.

One example of the thermoelectric conversion module according to the present invention would be a thermoelectric conversion module having a plurality of P-type thermoelectric conversion elements and a plurality of N-type thermoelectric conversion elements and formed by electrically connecting the plurality of P-type thermoelectric conversion elements with the plurality of N-type thermoelectric conversion elements in series, wherein at least one type of the thermoelectric conversion element is constituted by the thermoelectric conversion element that constitutes a crystal grain laminated in a transverse direction in which a length in a longitudinal direction of the crystal grain is longer than a length in the transverse direction using at least some of crystal grains constituting the sintered body.

### Advantageous Effects of Invention

According to the present invention, there can be provided a thermoelectric conversion element and a thermoelectric conversion module capable of ensuring a temperature difference between the front and the rear of the thermoelectric conversion element in a high-temperature environment and presenting a high power generation performance.

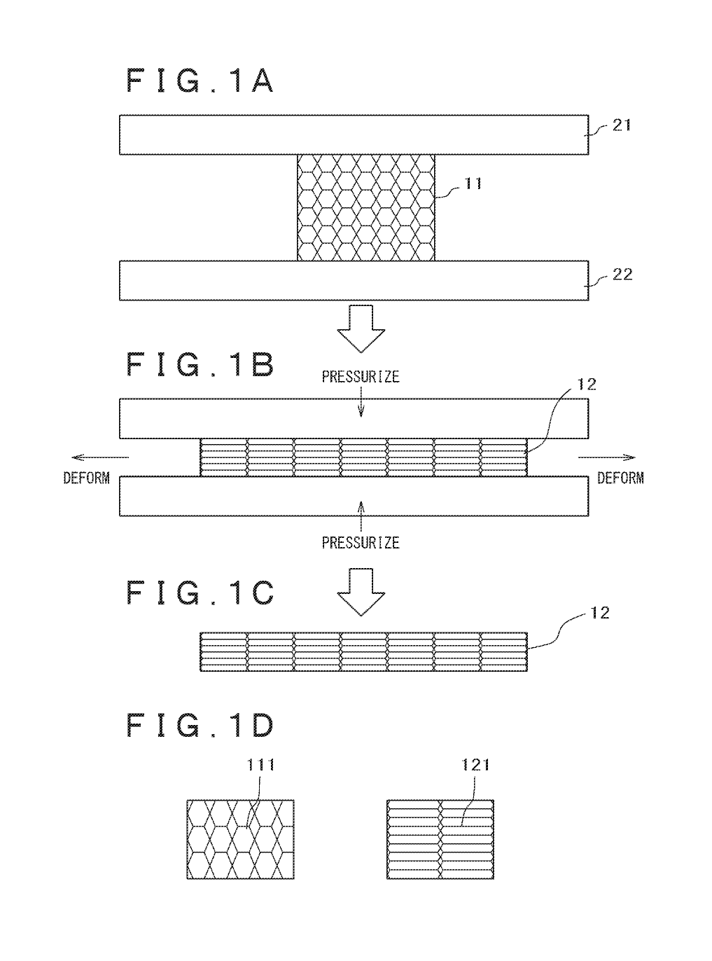

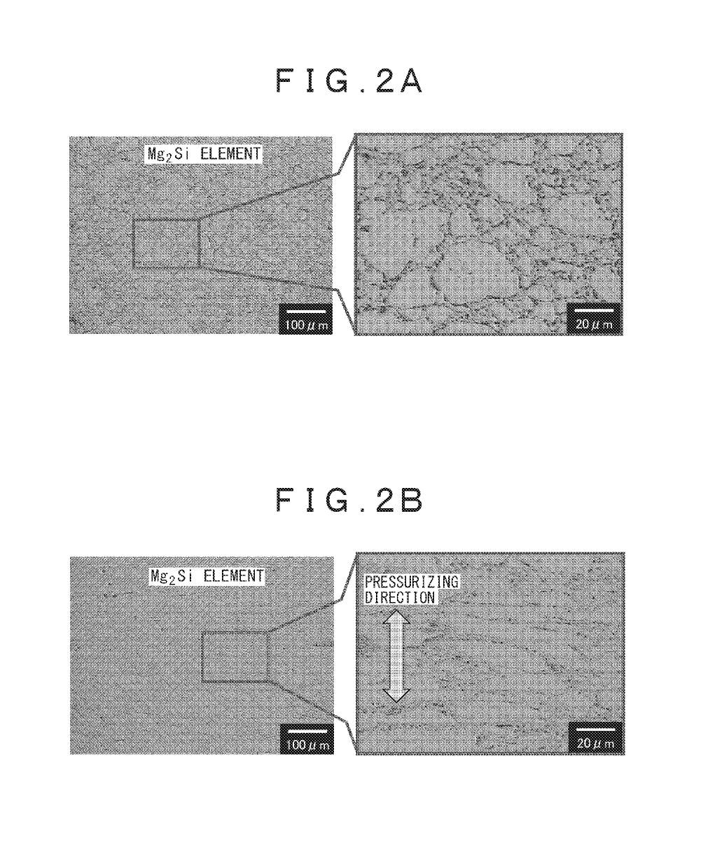

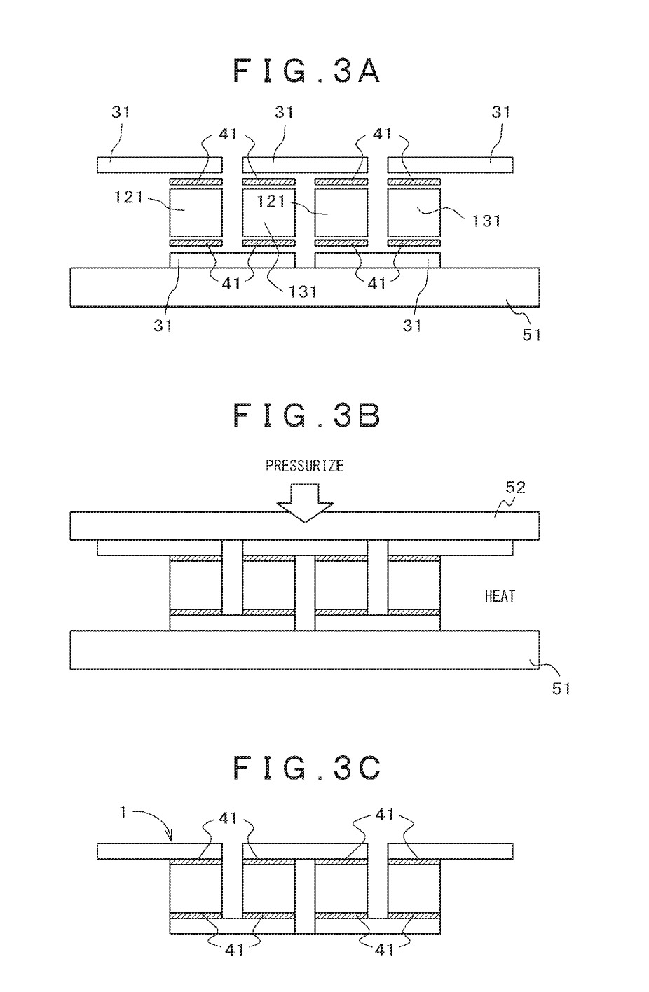

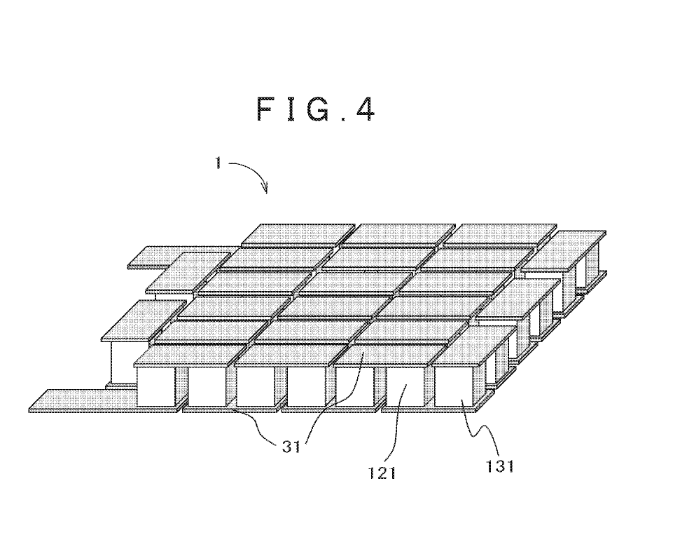

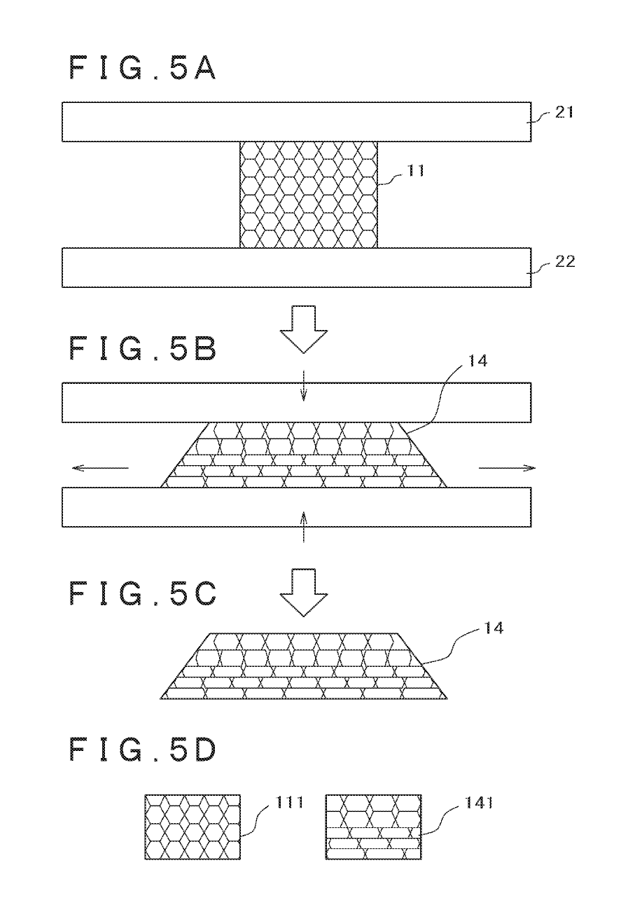

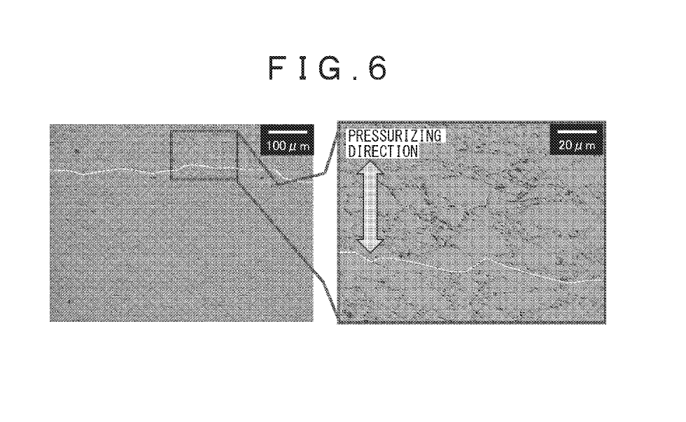

### BRIEF DESCRIPTION OF DRAWINGS

[FIG. 1A to 1D] A flow side view showing a method of manufacturing a thermoelectric conversion element according to a first embodiment of the present invention.

[FIG. 2A] An exemplary cross-sectional picture of a crystalline structure in the thermoelectric conversion element that does not undergo a plastic forming according to the first embodiment of the present invention.

[FIG. 2B] An exemplary cross-sectional picture of a crystalline structure in the thermoelectric conversion element that undergoes a plastic forming according to the first embodiment of the present invention.

[FIG. 3A to 3C] A flow side view showing a method of manufacturing a thermoelectric conversion module using the thermoelectric conversion element according to the first embodiment of the present invention.

[FIG. 4] A perspective view showing an example of the thermoelectric conversion module according to the first embodiment of the present invention.

[FIG. 5A to 5D] A flow side view showing a method of manufacturing a thermoelectric conversion element according to a second embodiment of the present invention.

[FIG. 6] An exemplary cross-sectional picture of a crystalline structure in the thermoelectric conversion element according to the second embodiment of the present invention.

### DESCRIPTION OF EMBODIMENTS

Hereinbelow, embodiments of the present invention are described with reference to drawings. It is noted that, in figures illustrating the embodiments, like elements are denoted by like reference designations and reference numerals, and repeated description thereof is omitted.

### First Embodiment

FIG. 1A to 1D is a flow side view showing a method of manufacturing a thermoelectric conversion element according to a first embodiment of the present invention. 11 donates a sintered body of a thermoelectric conversion material, 21 and 22 donate pressurizing tool, 12 donates the sintered body of the thermoelectric conversion element after being pressurized, 111 donates the thermoelectric conversion element produced from the sintered body before heating and pressurization, and 121 donates the thermoelectric conversion element produced from the sintered body after the heating and pressurization. The sintered body 11 of the thermoelectric conversion material was produced using the pulsed electric discharge sintering method in which the sintered body is produced using a discharge phenomenon by applying a voltage and a current to a grinding body of an Mg₂Si-based compound. By sintering the grinding powder of the Mg₂Si-based compound of 75 μm or smaller under vacuum at a sintering temperature of 730° C., at a sintering pressure of 60 MPa, and with a retention time of 30 minutes, the sintered body of the Mg₂Si-based compound was obtained. Although the sintered body 11 of the thermoelectric conversion element was obtained under the aforementioned sintering condition in this embodiment, it is possible to obtain the sintered body at the sintering temperature of 650 to 900° C., at the sintering pressure of 20-200 MPa, and with the retention time of 10 to 60 minutes. Although the Mg₂Si-based compound used in this embodiment contains aluminum, zinc, and/or manganese as a dopant, any dopant can be used for the Mg₂Si-based compound. In addition, this embodiment is not limited to the pulsed electric discharge sintering method, but the sintered body of the thermoelectric conversion material can be produced using the hot pressing method or the like.

In an effort of adjusting the crystalline structure in the sintered body 11 of the thermoelectric conversion material obtained by the pulsed electric discharge sintering method, the sintered body 11 of the thermoelectric conversion material is sandwiched between the pressurizing tool 21 and the pressurizing tool 22. By holding and heating and pressurizing the sintered body of the Mg₂Si-based compound at the retention temperature of 620° C., 120 MPa, temperature rising rate of 60° C./min., with retention time of 2 minutes, and under a nitrogen atmosphere, the bulk body 12 of the thermoelectric conversion material with its structure adjusted as shown in FIG. 1C was obtained. It can be seen that, in the bulk body 12 of the thermoelectric conversion material, the crystal grains are formed in a flattened manner by the Mg₂Si-based compound grains constituting the sintered body 11 of the thermoelectric conversion material being plastically deformed by being pressurized vertically while being heated at the same time as shown in FIG. 1B.

The term “flattened” used herein means that the horizontal size is larger than the vertical size of a member in terms of aspect ratio. In short, it means a state of being stretched in the pressurized direction. In other words, it means a rectangular or oval shape elongated in the pressurized direction. The vertical direction refers to the longitudinal direction of the thermoelectric conversion element, and the horizontal direction refers to the direction in which the electrode has its area. The phrase “long in the horizontal direction” is not necessarily indicated by a specific numeral value, and a flattened shape means that the height of a certain member in the vertical direction is larger than the width in the horizontal direction.

The term “flake” means that respective members do not have the same and uniform shape but they vary in the horizontal to vertical ratio or the aspect ratio and respectively have different shapes. A structure which is longer in the horizontal direction than in the vertical direction is also referred to as a flake structure.

Under the definition described above, “flake” is a wide-ranging concept, and the flake structure that is longer in the horizontal direction is referred to as a flattened structure.

As shown in FIG. 1D, the sintered body 11 of the thermoelectric conversion material and the bulk body 12 of the thermoelectric conversion material with the adjusted structure were cut out by the wire-saw process into cubes 3.7 mm on a side to form the thermoelectric conversion elements 111 and the thermoelectric conversion elements 121. Although the thermoelectric conversion element was processed using the wire-saw process herein, it has only to be cut out to a predetermined size, and any process can be used such as the dicing process, the water-jet process, the laser process, the wire electric discharge machining, and the like. Moreover, the shape of the thermoelectric conversion element is not limited to the cubic shape but various shapes are also possible such as a rectangular parallelepiped, a cylindrical column, a prism, and the like.

FIG. 2A shows a picture of the sectional structure of the thermoelectric conversion element 111 produced by cutting out of the sintered body 11 of the thermoelectric conversion material, and FIG. 2B shows a picture of the sectional structure of the thermoelectric conversion element 121 produced by cutting out of the bulk body 12 of the thermoelectric conversion material with its structure adjusted by further heating and pressurizing after the pulsed electric discharge sintering. It can be seen in FIG. 2A that the shape of the Mg₂Si-based compound grains is formed in an isotropic manner and a grain boundary is formed at an interface between the grains. On the other hand, in FIG. 2B, by plastically deforming the Mg₂Si-based compound grain into the flattened form, the shape of the Mg₂Si-based compound grain is anisotropically formed, thereby forming the laminar grain boundary horizontal to the pressurizing direction.

Thermal electrical conduction in a material is determined by an energy transfer by phonons and the energy transfer by carriers. Assuming the pressurizing direction in FIG. 2B as a heat flow direction, since numerous laminar grain boundary planes formed by plastically deforming the Mg₂Si-based compound grains not only promotes the scattering of phonons but also inhibits the transfer of carriers and thus also scatters the carriers, it can reduce the thermal electrical conduction in the heat flow direction. That is, by combining the thermoelectric conversion element into the thermoelectric conversion module using the pressurizing direction in FIG. 2B as the heat flow direction, it is possible to ensure the temperature difference between the front and the rear of the thermoelectric conversion element and also thereby to provide the thermoelectric conversion module presenting a high power generation performance. Furthermore, an operation under a high-temperature environment of 300 to 600° C. is also made possible. In the present invention, the temperature range of 300 to 600° C. is assumed as the high-temperature environment, but the temperature may not be strictly limited to the above range. Moreover, in such a case where it is operable temporarily at a higher temperature or the module will not be broken, it is included in the range of the high-temperature environment.

Although the heating and pressurizing condition for adjusting the structure of the Mg₂Si-based compound grain includes the retention temperature of 620° C., 120 MPa, the temperature rising rate of 60° C./min., the retention time of 2 minutes, and the nitrogen atmosphere, the heating and pressurizing condition can be variously selected depending on the diameter and shape of the Mg₂Si-based compound grain used for the pulsed electric discharge sintering or the aspect ratio of the Mg₂Si-based compound grain formed after the heating and pressurization.

Specifically, the retention temperature can be 300 to 900° C., the pressurization can be done at 30 to 200 MPa, the temperature rising rate can be 10 to 60° C./min., and the retention time can be 1 to 60 minutes.

The shape of the Mg₂Si-based compound grain formed after the heating and pressurization can exert its effect by taking its longitudinal direction perpendicular to the heat flow direction and making its length in the longitudinal direction two times or more of the length in the transverse direction. When the length in the longitudinal direction is less than two times of the length in the transverse direction, the effect of the laminar grain boundary may be weakened. However, the laminar grain boundary effect is only weakened but does not mean that the invention is not feasible at all, and the invention can be embodied as long as the length is longer in the longitudinal direction than in the transverse direction.

Although the heating and pressurizing step is included in this embodiment to allow the Mg₂Si-based compound grain in the sintered body 11 of the thermoelectric conversion material to have the anisotropy, the heating and pressurizing step may not necessarily be included. In that case, eliminating the heating and pressurizing step contributes to reduction of the production cost. When the heating and pressurizing step is not employed, by using the Mg₂Si-based compound grain in the flattened shape or the flake shape in the pulsed electric discharge sintering step for example, the bulk body 12 of the similarly anisotropic thermoelectric conversion material can be obtained.

Although the Mg₂Si-based compound is used as the N-type thermoelectric conversion material in this embodiment, other materials such as Mn₂Si, skutterudite system, and the like may also be used. Furthermore, the present invention is not limited to the N-type thermoelectric conversion material but it can be used for a P-type thermoelectric conversion material as well.

FIG. 3A to 3C is a flow side view of the method of manufacturing the thermoelectric conversion module using the thermoelectric conversion element 121 according to this embodiment. The thermoelectric conversion element 121 is an N-type thermoelectric conversion material produced from the Mg₂Si-based compound. A P-type thermoelectric conversion element 131 is preferably a thermoelectric conversion element of a combination of silicon-germanium system, iron-silicon system, bismuth-tellurium system, manganese-silicon system, lead-tellurium system, cobalt-antimony system, bismuth-antimony system, Heusler alloy system, half-Heusler alloy system, and the like. On the surface of the N-type thermoelectric conversion element 121 and the P-type thermoelectric conversion element 131, there may be formed a metallized film composed primarily of nickel, aluminum, titanium, molybdenum, manganese, tungsten, palladium, chromium, gold, silver, tin, magnesium, silicon, copper, and the like. The metallized film can be formed by any method such as the plating, the aerosol deposition, the flame gunning, the sputtering, the vapor deposition, the ion plating, the simultaneous unitary sintering, and the like. The primary component herein refers to an element contained by 90% in total as the primary component in the member that contains a plurality of elements. Although the primary component herein is as described above, the concept encompasses the case where the total percentage of the element used as the primary component is the largest among a plurality of elements contained in the member as the practical ratio. For example, when the electrode 31 is made of an alloy containing copper, nickel, and aluminum, if it contains copper by 34%, nickel by 33%, and aluminum by 33%, then copper can be referred to as the primary component. Otherwise, if it contains copper by 60%, nickel by 21%, and aluminum by 19%, then copper and nickel are primary components. The concept of the primary component remains the same even in the case of an alloy or a structure after bonding.

In this embodiment, the P-type thermoelectric conversion element is the manganese-silicon system. The electrode 31 may be of copper, nickel, aluminum, titanium, molybdenum, tungsten, iron, or an alloy composed primarily of any of the aforementioned metals, or a configuration of a plurality of layers laminated by any one or any alloy of the above.

The embodiment is described assuming the electrode 31 as nickel. A bonding material 41 is preferably of aluminum, nickel, tin, copper, zinc, germanium, magnesium, gold, silver, indium, lead, bismuth, tellurium, titanium, manganese, phosphor, or an alloy composed primarily of any one of these metals. The present assembly process will be described later assuming the bonding material 41 as an alloy composed primarily of aluminum.

First, as shown in FIG. 3A, the electrode 31 is placed on a support tool 51. Then on the electrode 31, the bonding material 41, the P-type thermoelectric conversion element 131 and the N-type thermoelectric conversion element 121, the bonding material 41, and the electrode 31 are layered in this order to be aligned and arranged. The P-type thermoelectric conversion element 131 and the N-type thermoelectric conversion element 121 are electrically connected in series with the electrode 31 interposed therebetween. It is desirable that all of the thermoelectric conversion elements included in the thermoelectric conversion module are electrically connected in series. In that case, it is possible to extract a high voltage.

Some of the elements may be arranged in parallel depending on the type of the electricity to be extracted. Because a lower voltage is obtained with the parallel connection, the current flowing through a single element can be reduced.

The explanation is given here assuming the bonding material 41 as a metallic foil, and the thickness of the bonding material 41 is preferably 1 to 500 μm. The bonding material 41 may be any metal that can be used for bonding. An experiment was made here using aluminum which represents high bondability. The thickness of the bonding material 41 has only to be smaller than the thickness of the electrode 31, as long as the bonding can be carried out. Within the range of 1 to 500 μm described above, the range with better bondability would be 1 to 20 μm.

However, when the bonding material 41 is too thin such as 1 μm, a variation in height of material to be bonded needs to be minimized as much as possible because it is difficult to absorb the variation in height of the material to be bonded at the time of bonding. Thus, given that the variation in height of the material to be bonded should be absorbed by the thickness of the bonding material 41, about 20 μm is more desirable. The value about 20 μm includes a margin of about 5 μm, which means between 15 and 25 μm. This is because this value is easy to control.

For these arrangements, the components may be arranged collectively using a tool (not shown) or individually, indifferent to the method thereof.

Next, as shown in FIG. 3B, both pressurization and heating are performed by a pressurizing tool 52 from the above to fuse the bonding material 41, thereby bonding the electrode 31 and the thermoelectric conversion elements 121 and 131 with the bonding material 41 interposed therebetween. The bonding pressure applied to the thermoelectric conversion element at this point is preferably 0.12 kPa or higher. Then, as shown in FIG. 3C, the thermoelectric conversion element assembly 1 can be formed by removing it from the pressurizing tool 51 and the support tool 52.

Although the description with reference to FIG. 3A to 3C shows the process of collectively bonding the top and bottom faces of the bonding material 41, one face may be bonded first and then the other face may be bonded later. For example, at the step shown in FIG. 3A, it is also possible to arrange the bonding material 41 and the thermoelectric conversion element only on the side of the support tool 51, heat the lower support tool 51 to fuse the bonding material 41 thereby bonding the thermoelectric conversion element and the electrode 31 on the side of the support tool 51, and then bonding the top face of the thermoelectric conversion element and the electrode 31 using the bonding material 41, thereby forming the thermoelectric conversion module assembly 1.

The pressurizing force is set to 0.12 kPa or higher here in order to prevent the P-type thermoelectric conversion element 131 and the N-type thermoelectric conversion element 121 from inclining at the time of bonding and to eject the bonding material 41 fused out of the interfaces between the P-type thermoelectric conversion element 131 and the N-type thermoelectric conversion element 121 and the electrode 31 as much as possible. An upper limit of the pressurizing force is not particularly specified, but it should be equal to or lower than the crushing strength of the element so that the element will not be broken. Specifically, it may be about 500 MPa or lower, but the pressure in the order of a few MPa can achieve a sufficient effect in this embodiment.

The bonding atmosphere has only to be a non-oxidizing atmosphere, and specifically a vacuum atmosphere, a nitrogen atmosphere, a nitrogen-oxygen mixture atmosphere, an argon atmosphere, and the like can be used.

Although this embodiment uses the metallic foil as the bonding material 41, other materials such as aluminum alloy powder can also be used. In such a case, a single type of powder may be used, layers formed of different types of powder may be laminated, or a mixture of these different types of powder may be used. When using such powder, a compact of powder alone may be arranged only in a location of bonding the P-type thermoelectric conversion element 131 and the N-type thermoelectric conversion element 121, or the powder may be applied only to the location of bonding the thermoelectric conversion element, or the powder made into the form of paste using resin or the like may also be applied to the location of bonding the thermoelectric conversion element. The manufacturing process can be further simplified, because the step of arranging the foil can be eliminated by applying the powder in advance. It is also possible to eliminate the step of arranging the foil in the similar manner by forming a metallization containing aluminum on the surface of the thermoelectric conversion element in advance or by forming a layer containing aluminum on the surface of the electrode 31. To form the aluminum-containing layer on the electrode, various methods can be selected such as the clad rolling, the aerosol deposition, the flame gunning, and the like. These formation methods are applicable not only to the aluminum-containing alloy but also to other materials.

As a variation of the method of manufacturing the thermoelectric conversion element shown in FIG. 1A to 1D, the structure of the sintered body of the thermoelectric conversion material may be adjusted when bonding the thermoelectric conversion element 121 to the electrode 31 shown in FIG. 3B. That is, as shown in FIG. 3B, both pressurization and heating are performed by a pressurizing tool 52 from the above to bond the electrode 31 to the thermoelectric conversion elements 121 and 131 with the bonding material 41 interposed therebetween, as well as the Mg₂Si-based compound grain constituting the sintered body of the thermoelectric conversion material is plastically deformed to be flattened. By performing the structure adjustment of the sintered body and the bonding of the electrode, the number of manufacturing steps can be reduced.

FIG. 4 shows a perspective view of an example of the thermoelectric conversion module according to the first embodiment of the present invention, in which 46 thermoelectric conversion elements are arranged and bonded in a latticed pattern. Based on the process shown in FIG. 3A to 3C, the thermoelectric conversion module assembly shown in FIG. 4 is manufactured. In FIG. 4, 121 denotes the N-type thermoelectric conversion element, 131 denotes the P-type thermoelectric conversion element, and 31 denotes the electrode. This thermoelectric conversion module may be used as encapsulated in a case or as it is.

As described in the first embodiment, by using the thermoelectric conversion element having anisotropic crystal grain in the sintered body, it is possible to ensure the temperature difference generated between the electrodes 31 on the top and bottom sides, and to provide the thermoelectric conversion element and the thermoelectric conversion module with the excellent power generation performance.

### Second Embodiment

A second embodiment of the present invention is described below with reference to FIG. 5A to 5D. FIG. 5A to 5D is a flow side view showing a method of manufacturing the thermoelectric conversion element. 11 denotes the sintered body of the thermoelectric conversion material, 21 and 22 denote pressurizing tools, 14 denotes the sintered body of the thermoelectric conversion element after pressurization, 111 denotes the thermoelectric conversion element produced from the sintered body before pressurization, and 141 denotes the thermoelectric conversion element produced from the sintered body after heating and pressurization. The method of producing the sintered body of the thermoelectric conversion material, the step of heating and pressurizing after producing the sintered body, and the step of cutting out the thermoelectric conversion elements are similar to those in the first embodiment. It is different from the first embodiment in that some of the Mg₂Si-based compound grains are plastically deformed preferentially to form the laminar grain boundary horizontal to the pressurizing direction during the heating and pressurizing step after the pulsed electric discharge sintering.

FIG. 6 shows the sectional structure of the element 141 cut out after heating and pressurizing the thermoelectric conversion element sintered body. It can be seen that the Mg₂Si-based compound grains are preferentially deformed into the flattened form below dotted lines in FIG. 6. When a large number of crystal grain boundaries are formed in layers with respect to the heat flow direction of the thermoelectric element, carriers are also scattered at the crystal grain boundaries, which reduces the thermal electrical conduction of the thermoelectric conversion element sintered body and also give a rise to a concern about increase in electric resistivity. By partially forming the laminar grain boundaries according to this embodiment, it is possible to inhibit the increase in electric resistivity and reduce the thermal electrical conduction. It is also possible to improve the power generation performance of the thermoelectric conversion element by constituting the layered crystal grain boundaries not only in the lower portion as shown in FIG. 5A to 5D but also in the upper portion or in multiple portions including both the upper and lower portions of the thermoelectric conversion element sintered body.

The heating and pressurizing step may not necessarily be included as with the first embodiment. For example, by using the Mg₂Si-based compound grain in the flattened shape or flake shape and the Mg₂Si-based compound grain substantially in the spherical shape during the pulsed electric discharge sintering step, it is possible to obtain the bulk body 13 of the thermoelectric conversion material partially forming the laminar grain boundary as in the heating and pressurizing step. For the pulsed electric discharge sintering condition, the heating and pressurizing condition after the pulsed electric discharge sintering, and the method of cutting out the thermoelectric conversion elements, various selections are available as in the first embodiment. The thermoelectric conversion module can also be manufactured in the same method as in the first embodiment, whereby it is possible to provide the thermoelectric conversion module with the excellent power generation performance.

### LIST OF REFERENCE SIGNS

1 Thermoelectric conversion element assembly
11 Sintered body of thermoelectric conversion material
111 Thermoelectric conversion element produced from sintered body before heating and pressurization
12 Bulk body of thermoelectric conversion material after heating and pressurization
121 Thermoelectric conversion element produced from sintered body after heating and pressurization
131 P-type thermoelectric conversion element
14 Bulk body of thermoelectric conversion material after heating and pressurization
141 Thermoelectric conversion element produced from sintered body after heating and pressurization
21, 22 Pressurizing tool
31 Electrode
41 Bonding material
51 Support tool
52 Pressurizing tool

1. A thermoelectric conversion element comprising a sintered body,
wherein a crystal grain laminated in a transverse direction in which a length in a longitudinal direction of the crystal grain is longer than a length in the transverse direction is constituted using at least some of crystal grains constituting the sintered body.

2. The thermoelectric conversion element according to claim 1,
wherein the crystal grains constituting the sintered body partially form a laminar grain boundary.

3. The thermoelectric conversion element according to claim 1,
wherein the sintered body is composed primarily of magnesium and silicon.

4. A method of manufacturing a thermoelectric conversion element including a sintered body, comprising the step of:
forming a crystal grain laminated in a transverse direction in which a length in a longitudinal direction is longer than a length in the transverse direction by heating and pressurizing the sintered body in a uniaxial direction.

5. The method of manufacturing the thermoelectric conversion element according to claim 4,
wherein the sintered body is sandwiched by a pressurizing tool to be pressurized while being heated.

6. The method of manufacturing the thermoelectric conversion element according to claim 4,
wherein the sintered body is heated and pressurized in a uniaxial direction when bonding an electrode to the sintered body.

7. The method of manufacturing the thermoelectric conversion element according to claim 4,
wherein the sintered body is produced by the pulsed electric discharge sintering method or the hot pressing method.

8. The method of manufacturing the thermoelectric conversion element according to claim 4,
wherein the sintered body is composed primarily of magnesium and silicon.

9. A method of manufacturing a thermoelectric conversion element including a sintered body, comprising the step of:
forming a crystal grain laminated in a transverse direction in which a length in a longitudinal direction is longer than a length in the transverse direction using at least some of crystal grains constituting the sintered body by sintering a compound in a flattened shape or a flake shape.

10. The method of manufacturing a thermoelectric conversion element according to claim 9, comprising the step of:
forming a crystal grain partially laminated in a transverse direction in which a length in a longitudinal direction is longer than a length in the transverse direction by sintering a compound in a flattened or flake shape and a compound in a spherical shape using at least some of crystal grains constituting the sintered body.

11. The method of manufacturing a thermoelectric conversion element according to claim 9,
wherein the sintered body is composed primarily of magnesium and silicon.

12. A thermoelectric conversion module having a plurality of P-type thermoelectric conversion elements and a plurality of N-type thermoelectric conversion elements and formed by electrically connecting the plurality of P-type thermoelectric conversion elements with the plurality of N-type thermoelectric conversion elements in series,
wherein at least one type of the thermoelectric conversion element is constituted by the thermoelectric conversion element that constitutes a crystal grain laminated in a transverse direction in which a length in a longitudinal direction of the crystal grain is longer than a length in the transverse direction using at least some of crystal grains constituting the sintered body.

13. The thermoelectric conversion module according to claim 12,
wherein the crystal grains constituting the sintered body partially form a laminar grain boundary.

14. The thermoelectric conversion module according to claim 12,
wherein the sintered body is composed primarily of magnesium and silicon.
